(19) United States
(12) Patent Application Publication
(10) Pub. No.: US 2026/0040845 A1
(43) Pub. Date: Feb. 5, 2026

(54) TREATMENTS TO CONTROL THICKNESS OF OXYGEN-CONTAINING MATERIALS

(71) Applicant: Applied Materials, Inc., Santa Clara, CA (US)

(72) Inventors: Akshat Jain, Sunnyvale, CA (US); Sankgeeth Vennila Sigamani, Santa Clara, CA (US); Mandar B. Pandit, Milpitas, CA (US); Praket Prakash Jha, San Jose, CA (US); Jingmei Liang, San Jose, CA (US); Yu-Wei Wu, San Jose, CA (US)

(73) Assignee: Applied Materials, Inc., Santa Clara, CA (US)

(21) Appl. No.: 18/790,057

(22) Filed: Jul. 31, 2024

(51) Int. Cl. H01L 21/02

(52) U.S. Cl. CPC H01L 21/02337; H01L 21/02164; H01L 21/02214; H01L 21/02274

(57) ABSTRACT

Exemplary processing methods may include providing one or more deposition precursors to a processing region of a semiconductor processing chamber. A substrate including a plurality of layers of a silicon-containing material may be housed within the processing region. Adjacent layers of the silicon-containing material may be vertically spaced apart to define a plurality of lateral gaps. One or more features may extend through the plurality of layers of the silicon-containing material and into the substrate. The methods may include depositing a flowable oxygen-containing material on the substrate in the plurality of lateral gaps and in the one or more features extending into the substrate. The methods may include providing a hydrogen-containing precursor to the processing region of the semiconductor processing chamber. The methods may include contacting the substrate with the hydrogen-containing precursor while applying a bias power. The contacting may reduce a thickness of the flowable oxygen-containing material.

### TECHNICAL FIELD

The present technology relates to semiconductor processing. More specifically, the present technology relates to methods of depositing and treating materials including flowable materials.

### BACKGROUND

Integrated circuits are made possible by processes which produce intricately patterned material layers on substrate surfaces. Producing patterned material on a substrate requires controlled methods of depositing and removal of exposed material. As device sizes continue to shrink, material deposition may affect subsequent operations. For example, in some gap filling operations, such as for a fin field-effect transistor (finFET) or a multi-channel field-effect transistor (mCFET), lateral gaps between nanosheets may need formation of gap filling material to serve as isolation between nanosheets. While a flowable deposition may selectively deposit material in these lateral gaps, some material may form in shallow trench isolation structures within the substrate. This material can impact device performance and subsequent processing operations.

Thus, there is a need for improved systems and methods that can be used to produce high quality devices and structures. These and other needs are addressed by the present technology.

### SUMMARY

Exemplary processing methods may include providing one or more deposition precursors to a processing region of a semiconductor processing chamber. A substrate including a plurality of layers of a silicon-containing material may be housed within the processing region. Adjacent layers of the silicon-containing material may be vertically spaced apart to define a plurality of lateral gaps. One or more features may extend through the plurality of layers of the silicon-containing material and into the substrate. The methods may include depositing a flowable oxygen-containing material on the substrate. The flowable oxygen-containing material may form in the plurality of lateral gaps and in the one or more features extending into the substrate. The methods may include providing a hydrogen-containing precursor to the processing region of the semiconductor processing chamber. The methods may include contacting the substrate with the hydrogen-containing precursor while applying a bias power. The contacting may reduce a thickness of the flowable oxygen-containing material in the one or more features extending into the substrate.

In some embodiments, the one or more deposition precursors may include a silicon-containing precursor and an oxygen-containing precursor. The silicon-containing material may be or include a silicon-and-germanium-containing material. The substrate may further include a polysilicon material overlying the plurality of layers of the silicon-containing material. The substrate may further include a hardmask material overlying the polysilicon material. The methods may include forming remote plasma effluents of the one or more deposition precursors in a remote plasma system of the semiconductor processing chamber. The hydrogen-containing precursor may be or include diatomic hydrogen (H₂). The methods may include providing one or more inert precursors to the processing region with the hydrogen-containing precursor. The bias power may be less than or about 1,000 W. The methods may induce pulsing the bias power while contacting the substrate with the hydrogen-containing precursor. A duty cycle of the bias power may be less than or about 25%. Contacting the substrate with the hydrogen-containing precursor may remove hydrogen from the flowable oxygen-containing material.

Some embodiments of the present technology may encompass semiconductor processing methods. The methods may include providing one or more deposition precursors to a semiconductor processing chamber. A substrate including a plurality of layers of silicon-and-germanium-containing material may be housed within a processing region of the semiconductor processing chamber. Adjacent layers of silicon-and-germanium-containing material may be vertically spaced apart to define a plurality of lateral gaps. One or more features may extend through the plurality of layers of silicon-and-germanium-containing material and into the substrate. The methods may include forming plasma effluents of the one or more deposition precursors. The methods may include depositing a flowable oxygen-containing material on the substrate. The flowable oxygen-containing material may form in the plurality of lateral gaps and in the one or more features extending into the substrate. The methods may include providing a hydrogen-containing precursor to the processing region of the semiconductor processing chamber. The methods may include contacting the substrate with the hydrogen-containing precursor while applying a pulsed bias power. The contacting may reduce a thickness of the flowable oxygen-containing material in the one or more features extending into the substrate.

In some embodiments, the plasma effluents of the one or more deposition precursors may be formed in a remote plasma system of the semiconductor processing chamber. The pulsed bias power may be less than or about 750 W. The pulsed bias power may be pulsed at a frequency of less than or about 20 Hz. A pressure within the processing region may be maintained at less than or about 1 Torr while contacting the substrate with the hydrogen-containing precursor.

Some embodiments of the present technology may encompass semiconductor processing methods. The methods may include providing one or more deposition precursors to a remote plasma system of a semiconductor processing chamber. The methods may include forming plasma effluents of the one or more deposition precursors. The methods may include providing the plasma effluents of the one or more deposition precursors to a processing region of the semiconductor processing chamber. A substrate including a plurality of layers of a silicon-and-germanium-containing material may be housed within the processing region. Adjacent layers of the silicon-and-germanium-containing material may be vertically spaced apart to define a plurality of lateral gaps. One or more features may extend through the plurality of layers of the silicon-and-germanium-containing material and into the substrate. The methods may include depositing a flowable oxygen-containing material on the substrate. The flowable oxygen-containing material may form in the plurality of lateral gaps and in the one or more features extending into the substrate. The methods may include providing a hydrogen-containing precursor to the processing region of the semiconductor processing chamber. The methods may include contacting the substrate with the hydrogen-containing precursor while applying a pulsed bias power. The contacting may reduce a thickness of the flowable oxygen-containing material in the one or more features extending into the substrate while maintaining an amount of flowable oxygen-containing material in the plurality of lateral gaps.

In some embodiments, the pulsed bias power may be pulsed at a frequency of less than or about 20 Hz and at a power of less than or about 1,000 W. Contacting the substrate with the hydrogen-containing precursor may densify the flowable oxygen-containing material in the one or more features extending into the substrate. A temperature within the processing region may be maintained at less than or about 160° C. while depositing the flowable oxygen-containing material on the substrate.

Such technology may provide numerous benefits over conventional systems and techniques. For example, by performing a post-deposition treatment, a vertical thickness of the deposited material may be reduced. Additionally, by using only a bias power during the post-deposition treatment, thickness of material in lateral gaps, where material is desired to be maintained, may not be shrunk. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a processing method according to some embodiments of the present technology.

FIGS. 3A-3C show schematic cross-sectional views of a substrate during a processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Dielectric materials, such as silicon oxide, may be used in semiconductor device manufacturing for a number of structures and processes, including as an isolation material, for example as an isolation material between nanosheets. In gap filling operations, some processing may utilize flowable films formed under process conditions to limit conformality of deposition, which may allow the deposited material to better fill lateral gaps between nanosheets on the substrate. Flowable silicon material may be characterized by relatively high amounts of hydrogen, and may be less dense than other formed films.

As feature sizes continue to shrink, flowable films may be challenged for narrow features, such as lateral gaps between nanosheets on the substrate, which may be further characterized by higher aspect ratios. While the lateral gaps may be filled with material, material may also form in one or more features extending into the substrate. As this material may not be desired, conventional technologies have attempted to prevent or reduce deposition of this material. However, preventing or reducing deposition of material in one or more features extending into the substrate may result in uncomplete filling of the lateral gaps. The present technology may overcome these limitations by performing a post-deposition treatment of material formed in the feature and extending into the substrate that may not be performed on material deposited in the lateral gaps. The post-deposition treatment may utilize a biased hydrogen treatment that reduces a thickness of the material mainly in the vertical direction. Since only vertical surfaces of the lateral gaps may be exposed, the post-deposition treatment may not reduce a thickness of material deposited in the lateral gaps. Instead, the post-deposition treatment may reduce a thickness of material in the one or more features extending into the substrate.

After describing general aspects of a chamber according to some embodiments of the present technology in which plasma processing operations discussed below may be performed, specific methodology may be discussed. It is to be understood that the present technology is not intended to be limited to the specific films, chambers, or processing discussed, as the techniques described may be used to improve a number of film formation processes, and may be applicable to a variety of processing chambers and operations.

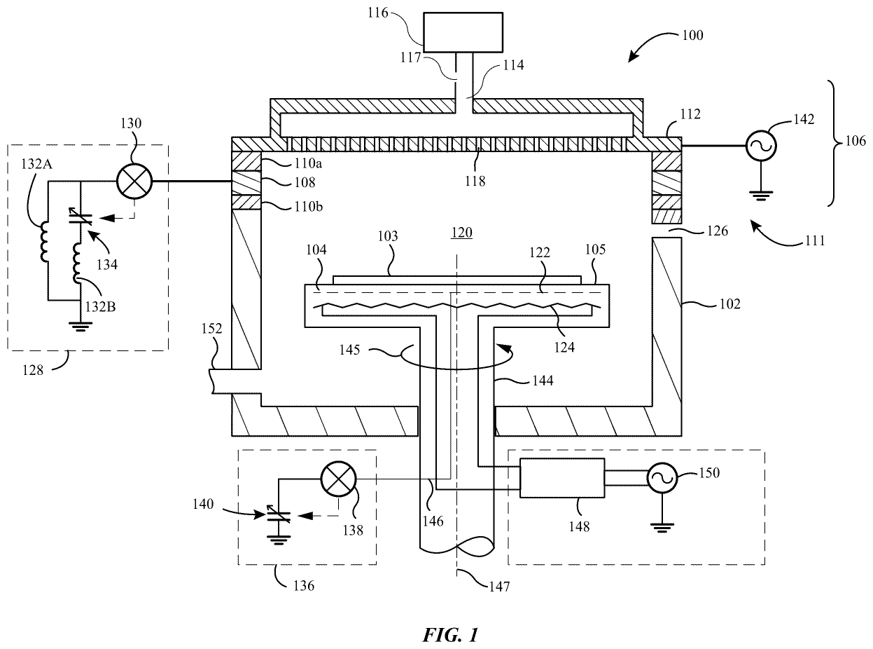

FIG. 1 shows a cross-sectional view of an exemplary processing chamber 100 according to some embodiments of the present technology. The figure may illustrate an overview of a system incorporating one or more aspects of the present technology, and/or which may perform one or more deposition or other processing operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Inlet 114 may include delivery from a remote plasma system 116, which may be fluidly coupled with the chamber, as well as a bypass 117 for process gas delivery that may not flow through the remote plasma system 116 in some embodiments. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

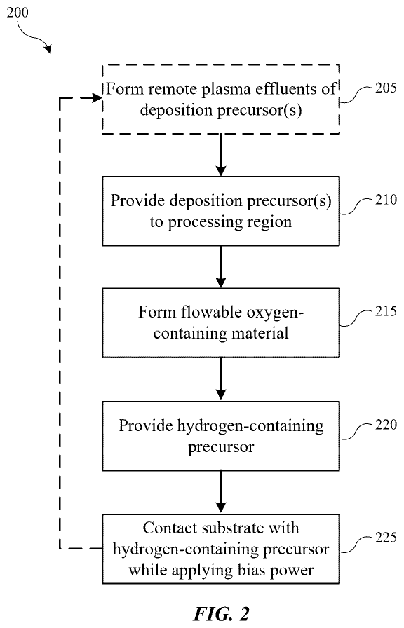

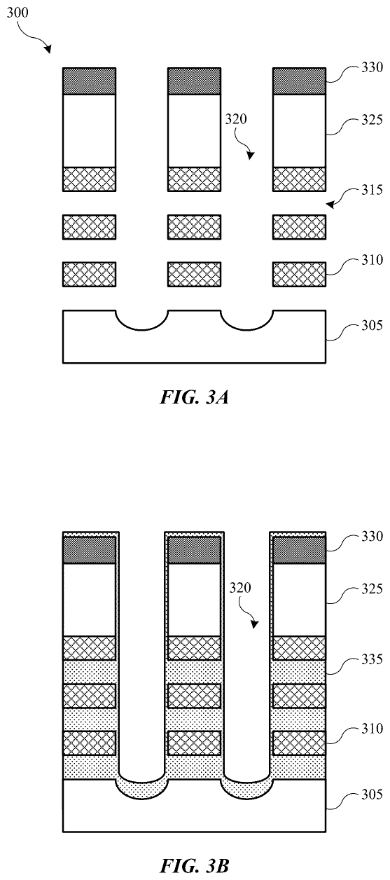

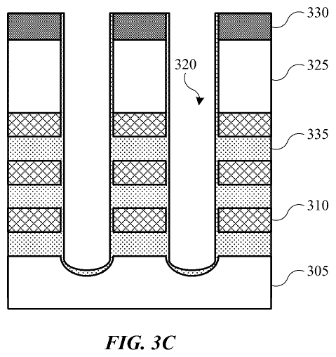

Processing chamber 100 may be utilized in some embodiments of the present technology for processing methods that may include deposition, treatment, etching, and/or conversion of materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3C, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a semiconductor substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

A substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. Substrate 305 may be any number of materials used in semiconductor processing. The substrate 305 material may be or include silicon, germanium, dielectric materials including silicon oxide or silicon nitride, metal materials, or any number of combinations of these materials, which may be the substrate 305, or materials formed in structure 300. The substrate 305 may include a plurality of layers of a silicon-containing material 310. The plurality of layers of the silicon-containing material 310 may be nanosheets in a field-effect transistor (FET), such as a fin field-effect transistor (finFET) or a multi-channel field-effect transistor (mCFET). In embodiments, the silicon-containing material may be or include a silicon-and-germanium-containing material. Adjacent layers, or pairs, of the silicon-containing material may be vertically spaced apart to define a plurality of lateral gaps 315. A sacrificial or dummy material may previously be present in the lateral gaps 315, but may be removed prior to method 200. One or more features 320 may extend through the plurality of layers of the silicon-containing material 310 and into the substrate 305. Features 320 may be characterized by any shape or configuration according to the present technology. In some embodiments, the features 320 may be or include a trench or aperture.

In embodiments, the substrate 305 may further include a polysilicon material 325 overlying the plurality of layers of the silicon-containing material 310. A hardmask material 330 may overly the polysilicon material 325. It is contemplated that the structure 300 is not limited by these layers and that any other number, order, or configuration of materials may be present.

The lateral gaps 315 may be characterized by a height, or dimension between adjacent layers of the silicon-containing material 310, between about 1 nm and about 50 nm, such as between about 2 nm and about 25 nm, between about 3 nm and about 25 nm, between about 4 nm and about 20 nm, between about 5 nm and about 15 nm, or by any other range. The lateral gaps 315 may be characterized by a width, or dimension between adjacent features 320, between about 10 nm and about 90 nm, such as between about 12 nm and about 80 nm, between about 14 nm and about 70 nm, between about 16 nm and about 60 nm, between about 17 nm and about 50 nm, between about 20 nm and about 40 nm, between about 20 nm and about 30 nm, or by any other range.

Although the features 320 may be characterized by any shapes or sizes, in some embodiments the features 320 may be characterized by higher aspect ratios, or a ratio of a depth of the feature to a width across the feature. For example, in some embodiments, features 320 may be characterized by aspect ratios greater than or about 2:1, and may be characterized by an aspect ratio greater than or about 3:1, greater than or about 4:1, greater than or about 5:1, greater than or about 6:1, greater than or about 7:1, greater than or about 8:1, greater than or about 9:1, greater than or about 10:1, or greater. Additionally, the features may be characterized by narrow widths or diameters across the feature including between two sidewalls, such as a dimension less than or about 20 nm, and may be characterized by a width across the feature of less than or about 15 nm, less than or about 12 nm, less than or about 10 nm, less than or about 9 nm, less than or about 8 nm, less than or about 7 nm, less than or about 6 nm, less than or about 5 nm, or less.

Method 200 may include providing one or more deposition precursors to a processing region of the semiconductor processing chamber housing the structure 300. In some embodiments, method 200 may include forming a remote plasma of some or all of the one or more deposition precursors. Accordingly, method 200 may include providing one or more deposition precursors to a remote plasma system of the semiconductor processing chamber, such as remote plasma system 116, at optional operation 205. Method 200 may include forming plasma effluents of some or all of the one or more deposition precursors in the remote plasma system. In other embodiments, such as where remote plasma effluents are not formed, method 200 may include providing the one or more deposition precursors directly to the processing region of a semiconductor processing chamber, such that the remote plasma system 116 may be bypassed. Regardless of whether the deposition precursors are plasma-enhanced, method 200 may include providing the one or more deposition precursors, or plasma effluents thereof, to the processing region of the semiconductor processing chamber at operation 210.

The deposition precursors may include one or more silicon-containing precursors, one or more oxygen-containing precursors, and/or one or more diluents or carrier gases such as an inert gas or other gas delivered with the silicon-containing precursor and/or the oxygen-containing precursor. Silicon-containing precursors that may be used during operation 210 may include, but are not limited to, silane (SiH₄), disilane (Si₂H₆), trisilane, or other organosilanes including cyclohexasilanes, silicon tetrafluoride (SiF₄), silicon tetrachloride (SiCl₄), dichlorosilane (SiH₂Cl₂), tetraethyl orthosilicate (TEOS), as well as any other silicon-containing precursors that may be used in silicon-containing material deposition. By utilizing higher order silanes, longer material chains may be produced, which may increase flowability in some embodiments. Oxygen-containing precursors used during operation 210 may include, but are not limited to, diatomic oxygen (O₂), nitrous oxide (N₂O), nitrogen dioxide (NO₂), ozone (O₃), water or steam (H₂O), as well as any other oxygen-containing precursors that may be used in silicon-containing material deposition. In any of the operations one or more additional precursors may be included, such as inert precursors, which may include argon (Ar), helium (He), xenon (Xe), krypton (Kr), or other materials such as diatomic nitrogen (N₂), ammonia (NH₃), diatomic hydrogen (H₂), or other precursors.

When plasma effluents of some or all of the one or more deposition precursors in the remote plasma system are formed, the power applied may be a lower power plasma, which may limit dissociation, and which may maintain an amount of hydrogen incorporation in the deposited materials. This incorporated hydrogen may contribute to the flowability of the materials formed. The process may include utilizing a source power in the remote plasma system. The source power may be used to perform a controlled dissociation of the silicon-containing precursor, which may limit dissociation and allow longer material chains to be formed. When these materials contact the substrate 305, the longer chain silicon-containing materials may have increased flowability, which may improve fill in the lateral gaps 315.

In embodiments, the source power may be applied at a higher frequency, such as greater than or about 10 MHz, greater than or about 13 MHz, greater than or about 15 MHz, greater than or about 20 MHz, or higher. The plasma power source may deliver a source power of less than or about 500 W, and may deliver a power of less than or about 450 W, less than or about 400 W, less than or about 350 W, less than or about 300 W, less than or about 250 W, less than or about 200 W, less than or about 150 W, or less. Additionally, the source power may be pulsed at a pulsing frequency of 20 kHz or less, such as less than or about 15 kHz, less than or about 12 kHz, less than or about 10 kHz, less than or about 8 kHz, or less. Additionally, the pulsing duty cycle may be applied at less than or about 50%, and may be applied at less than or about 40%, less than or about 30%, less than or about 20%, less than or about 10%, less than or about 5%, less than or about 1%, less than or about 0.75%, less than or about 0.5%, or less. Selecting the frequency, source power, pulsing frequency, and/or duty cycle may limit the silicon precursor dissociation, and improve long-chain formation.

After the one or more deposition precursors are provided to the processing region, an oxygen-containing material 335 may be formed on the substrate at operation 215. In embodiments, the oxygen-containing material 335 may be a flowable or liquid-like material. The deposited materials may at least partially flow into the features 320 in the structure 300. As illustrated in FIG. 3B, oxygen-containing material 335 may form in the plurality of lateral gaps 315 and in the one or more features 320, such as the portions extending into the substrate 305. During operations 210-220, the substrate support 104 may rotate. This rotation may cause the oxygen-containing material 335 to flow into and remain in the lateral gaps 315. However, a portion of the oxygen-containing material 335 may also form and remain in the one or more features 320, such as the portions extending into the substrate 305. As illustrated, an amount of the oxygen-containing material 335 may remain on the sidewalls of the features 320, as well as material on top of, or between, features. Although the amount deposited in the features 320 extending into the substrate 305, on the sidewalls of the features 320, and/or on top of the features 320 may be relatively small, it may be desirable to remove these materials such that oxygen-containing material 335 mainly fills the lateral gaps 315. As such, the present technology may include a post-deposition treatment to reduce a thickness of the oxygen-containing material 335 extending into the substrate 305, on the sidewalls of the features 320, and/or on top of the features 320.

Subsequent an amount of oxygen-containing material 335 deposition, in the present technology may include a post-deposition treatment configured to reduce a thickness of the oxygen-containing material 335 extending into the substrate 305, on the sidewalls of the features 320, and/or on top of the features 320. The post-deposition treatment may be performed in the same chamber as the deposition, and may be performed in a cyclic process to fill the feature. In some embodiments, flows of some or all of the one or more deposition precursors may be halted, and the processing region may be purged. The flow of inert gases, such as Ar and/or He, may also be halted. Subsequent a purge, a hydrogen-containing precursor may be provided to the processing region of the semiconductor processing chamber at operation 220. In embodiments, the post-deposition treatment may utilize a hydrogen-containing precursor. However, it is also contemplated that a hydrogen-rich environment may be used. For example, the hydrogen-containing precursors may be provided with other precursors, such as Ar and/or He. Accordingly, some embodiments of method 200 may include maintaining the flow of inert gases between operation 215 and operation 220.

During the post-deposition treatment, a power source may be engaged and coupled with the substrate support to provide a bias to the hydrogen-containing precursor and, if present, other precursors. Method 200 may include contacting the substrate 305 and the oxygen-containing material 335 with the hydrogen-containing precursor while applying the bias power at operation 225. The bias power may draw post-deposition treatment precursors, such as the hydrogen-containing precursor, to the substrate 305, which may bombard the oxygen-containing material 335. The bombardment may remove loose hydrogen, such as dangling hydrogen bonds, from the oxygen-containing material 335, which may result in densification of the oxygen-containing material 335. The bombardment and removal of loose hydrogen, such as dangling hydrogen bonds, from the oxygen-containing material 335 may also result in shrinkage of the oxygen-containing material 335. Due to the bias power, which may increase directionality of the bombardment, the oxygen-containing material 335 may be densified and shrunk in mainly in the vertical direction. As such, the contacting at operation 225 may reduce a thickness of the oxygen-containing material 335 in the one or more features 320 extending into the substrate 305.

As previously discussed, a hydrogen-containing precursor may be provided at operation 220 with or without Ar and/or He. Hydrogen-containing precursors that may be used during operation 220 may include, but are not limited to, H₂, NH₃, diazine (N₂H₂), as well as any other hydrogen-containing precursors that may be used in semiconductor processing. Additionally, one or more additional precursors may be included, such as inert precursors, which may include Ar, He, Xe, Kr, or other materials.

A flow rate of the hydrogen-containing precursor may be relatively low to maintain ion density and prevent damage to structure 300 and/or substrate 305. For example, higher flow rates of the hydrogen-containing precursor may damage the substrate 305, such as silicon material of substrate 305, due to hydrogen diffusion. In embodiments, a flow rate of the hydrogen-containing precursor may be less than or about 4,500 sccm, and may be less than or about 4,000 sccm, less than or about 3,500 sccm, less than or about 3,000 sccm, less than or about 2,500 sccm, less than or about 2,000 sccm, less than or about 1,500 sccm, less than or about 1,000 sccm, less than or about 900 sccm, less than or about 800 sccm, less than or about 700 sccm, less than or about 600 sccm, less than or about 500 sccm, or less. Argon may be provided at less than or about 4,500 sccm, and may be less than or about 4,000 sccm, less than or about 3,500 sccm, less than or about 3,000 sccm, less than or about 2,500 sccm, less than or about 2,000 sccm, less than or about 1,500 sccm, less than or about 1,000 sccm, less than or about 900 sccm, less than or about 800 sccm, less than or about 700 sccm, less than or about 600 sccm, less than or about 500 sccm, or less. Helium may be provided at a flow rate of less than or about 2,000 sccm, and may be provided at a flow rate of less than or about 1,500 sccm, less than or about 1,000 sccm, less than or about 900 sccm, less than or about 800 sccm, less than or about 700 sccm, less than or about 600 sccm, less than or about 500 sccm, or less

Method 200 may not include forming plasma effluents of the treatment precursor, such as the hydrogen-containing precursor. As such, the processing region may be maintained plasma-free during operation 220 and operation 225. However, it is contemplated that plasma effluents of Ar and/or He may be formed, such as in the remote plasma system 116. Additionally, some plasma effluents of the treatment precursor, such as the hydrogen-containing precursor, may inadvertently form during operation 220 and operation 225. While a source power may not be applied, method 200 may include applying bias power while contacting the substrate with treatment precursor, such as the hydrogen-containing precursor.

The bias power, which may be applied as a 2 MHz frequency to substrate support 104, may be a relatively low bias power to maintain ion density and prevent damage to structure 300 and/or substrate 305. For example, higher bias power precursor may damage the substrate 305, such as silicon material of substrate 305. In embodiments, the bias power may be less than or about 1,000 W, and may be less than or about 900 W, less than or about 800 W, less than or about 750 W, less than or about 700 W, less than or about 650 W, less than or about 600 W, less than or about 550 W, less than or about 500 W, or less. Additionally, the bias power may be a pulsed bias power. The bias power may be pulsed at a pulsing frequency of 20 Hz or less, such as less than or about 15 Hz, less than or about 12 Hz, less than or about 10 Hz, less than or about 8 Hz, less than or about 6 Hz, less than or about 5 Hz, less than or about 2 Hz, or less. Additionally, to further lower the effective bias power, the duty cycle of the bias power may less than or about 50%, and may be less than or about 40%, less than or about 30%, less than or about 25%, less than or about 20%, less than or about 15%, less than or about 12%, less than or about 10%, less than or about 7%, less than or about 5%, less than or about 2%, or less. Selecting the frequency, source power, pulsing frequency, and/or duty cycle may limit the effective bias power and control the ion density and potential for damage to structure 300 and/or substrate 305.

As illustrated in FIG. 3C, the contacting at operation 225 may reduce the thickness of the oxygen-containing material 335 in the one or more features 320 extending into the substrate 305, which may be measured vertically or normal to the substrate 305. In embodiments, the contacting at operation 225 may reduce the thickness of the oxygen-containing material 335 by greater than or about 10%, and may reduce the thickness of the oxygen-containing material 335 by greater than or about 20%, greater than or about 25%, greater than or about 30%, greater than or about 35%, greater than or about 40%, greater than or about 45%, greater than or about 50%, or more. As also illustrated in FIG. 3C, the oxygen-containing material 335 formed in the one or more lateral gaps 315 may be maintained during the contacting at operation 225.

Temperature and pressure may also impact operations of the present technology. For example, in some embodiments to facilitate film flow, the process may be performed at a temperature below or about 160° C., and may be performed at a temperature less than or about 150° C., less than or about 140° C., less than or about 120° C., less than or about 100° C., less than or about 80° C., less than or about 60° C., less than or about 40° C., or lower. The temperature may be maintained in any of these ranges throughout the method. Increased temperatures, such as temperatures closer to 160° C. may form a more flowable material and result in less deposition where the one or more features 320 extend into the substrate 305. Pressure within the chamber may be kept relatively low for any of the processes as well, such as at a chamber pressure of less than or about 1 Torr, and pressure may be maintained at less than or about 900 mTorr, less than or about 800 mTorr, less than or about 700 mTorr, less than or about 600 mTorr, less than or about 500 mTorr, less than or about 400 mTorr, or less. The pressure may be maintained in any of these ranges throughout the method. Increased pressures, such as pressures closer to 900 mTorr may lower the ion density during the treatment operation, which may increase recombination of any ions formed and reduce damage to the structure 300. By performing processes according to some embodiments of the present technology, improved fill of smaller features, such as lateral gaps 315, utilizing silicon-containing materials may be produced.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a flowable oxygen-containing material” includes a plurality of such materials, and reference to “the features” includes reference to one or more features and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing one or more deposition precursors to a processing region of a semiconductor processing chamber, wherein a substrate comprising a plurality of layers of a silicon-containing material is housed within the processing region, wherein adjacent layers of the silicon-containing material are vertically spaced apart to define a plurality of lateral gaps, and wherein one or more features extend through the plurality of layers of the silicon-containing material and into the substrate;
depositing a flowable oxygen-containing material on the substrate, wherein the flowable oxygen-containing material forms in the plurality of lateral gaps and in the one or more features extending into the substrate;
providing a hydrogen-containing precursor to the processing region of the semiconductor processing chamber; and
contacting the substrate with the hydrogen-containing precursor while applying a bias power, wherein the contacting reduces a thickness of the flowable oxygen-containing material in the one or more features extending into the substrate.

2. The semiconductor processing method of claim 1, wherein the one or more deposition precursors comprise a silicon-containing precursor and an oxygen-containing precursor.

3. The semiconductor processing method of claim 1, wherein the silicon-containing material comprises a silicon-and-germanium-containing material.

4. The semiconductor processing method of claim 1, wherein the substrate further comprises:
a polysilicon material overlying the plurality of layers of the silicon-containing material; and
a hardmask material overlying the polysilicon material.

5. The semiconductor processing method of claim 1, further comprising:
forming remote plasma effluents of the one or more deposition precursors in a remote plasma system of the semiconductor processing chamber.

6. The semiconductor processing method of claim 1, wherein the hydrogen-containing precursor comprises diatomic hydrogen (H₂).

7. The semiconductor processing method of claim 1, further comprising:
providing one or more inert precursors to the processing region with the hydrogen-containing precursor.

8. The semiconductor processing method of claim 1, wherein the bias power is less than or about 1,000 W.

9. The semiconductor processing method of claim 1, further comprising:
pulsing the bias power while contacting the substrate with the hydrogen-containing precursor.

10. The semiconductor processing method of claim 1, wherein a duty cycle of the bias power is less than or about 25%.

11. The semiconductor processing method of claim 1, wherein contacting the substrate with the hydrogen-containing precursor removes hydrogen from the flowable oxygen-containing material.

12. A semiconductor processing method comprising:
providing one or more deposition precursors to a semiconductor processing chamber, wherein a substrate comprising a plurality of layers of silicon-and-germanium-containing material is housed within a processing region of the semiconductor processing chamber, wherein adjacent layers of silicon-and-germanium-containing material are vertically spaced apart to define a plurality of lateral gaps, and wherein one or more features extend through the plurality of layers of silicon-and-germanium-containing material and into the substrate;
forming plasma effluents of the one or more deposition precursors;
depositing a flowable oxygen-containing material on the substrate, wherein the flowable oxygen-containing material forms in the plurality of lateral gaps and in the one or more features extending into the substrate;
providing a hydrogen-containing precursor to the processing region of the semiconductor processing chamber; and
contacting the substrate with the hydrogen-containing precursor while applying a pulsed bias power, wherein the contacting reduces a thickness of the flowable oxygen-containing material in the one or more features extending into the substrate.

13. The semiconductor processing method of claim 12, wherein the plasma effluents of the one or more deposition precursors are formed in a remote plasma system of the semiconductor processing chamber.

14. The semiconductor processing method of claim 12, wherein the pulsed bias power is less than or about 750 W.

15. The semiconductor processing method of claim 12, wherein the pulsed bias power is pulsed at a frequency of less than or about 20 Hz.

16. The semiconductor processing method of claim 12, wherein a pressure within the processing region is maintained at less than or about 1 Torr while contacting the substrate with the hydrogen-containing precursor.

17. A semiconductor processing method comprising:
providing one or more deposition precursors to a remote plasma system of a semiconductor processing chamber;
forming plasma effluents of the one or more deposition precursors;
providing the plasma effluents of the one or more deposition precursors to a processing region of the semiconductor processing chamber, wherein a substrate comprising a plurality of layers of a silicon-and-germanium-containing material is housed within the processing region, wherein adjacent layers of the silicon-and-germanium-containing material are vertically spaced apart to define a plurality of lateral gaps, and wherein one or more features extend through the plurality of layers of the silicon-and-germanium-containing material and into the substrate;
depositing a flowable oxygen-containing material on the substrate, wherein the flowable oxygen-containing material forms in the plurality of lateral gaps and in the one or more features extending into the substrate;
providing a hydrogen-containing precursor to the processing region of the semiconductor processing chamber; and
contacting the substrate with the hydrogen-containing precursor while applying a pulsed bias power, wherein the contacting reduces a thickness of the flowable oxygen-containing material in the one or more features extending into the substrate while maintaining an amount of flowable oxygen-containing material in the plurality of lateral gaps.

18. The semiconductor processing method of claim 17, wherein the pulsed bias power is pulsed at a frequency of less than or about 20 Hz and at a power of less than or about 1,000 W.

19. The semiconductor processing method of claim 17, wherein contacting the substrate with the hydrogen-containing precursor densifies the flowable oxygen-containing material in the one or more features extending into the substrate.

20. The semiconductor processing method of claim 17, wherein a temperature within the processing region is maintained at less than or about 160° C. while depositing the flowable oxygen-containing material on the substrate.
